(19) United States
(12) Patent Application Publication
(10) Pub. No.: US 2024/0213187 A1
(43) Pub. Date: Jun. 27, 2024

(54) SEMICONDUCTOR PACKAGE AND METHOD FOR MANUFACTURING THE SAME

(71) Applicant: NEPES CO., LTD., Samseong-myeon (KR)

(72) Inventors: JungWon LEE, Samseong-myeon (KR); InSoo KANG, Samseong-myeon (KR); Ju-Eok PARK, Samseong-myeon (KR); Se-Bin HWANG, Samseong-myeon (KR)

(73) Assignee: NEPES CO., LTD., Samseong-myeon (KR)

(21) Appl. No.: 18/534,847

(22) Filed: Dec. 11, 2023

(30) Foreign Application Priority Data
Dec. 21, 2022 (KR) 10-2022-0180979

(51) Int. Cl. H01L 23/66; H01L 23/00; H01L 23/15; H01L 23/31; H01L 23/498; H01L 23/522; H01Q 1/22

(52) U.S. Cl. CPC H01L 23/66; H01L 23/15; H01L 23/3107; H01L 23/49816; H01L 23/49822; H01L 23/49838; H01L 23/5226; H01L 24/08; H01L 24/16; H01L 24/94; H01L 24/97; H01Q 1/2283; H01L 2223/6677; H01L 2224/08225; H01L 2224/16225; H01L 2224/94; H01L 2224/97; H01L 2924/181

(57) ABSTRACT

A semiconductor package and a manufacturing method thereof are disclosed. The semiconductor package and manufacturing method thereof according to an aspect of the present invention may include an antenna structure including a dielectric layer made of a transparent material, an active antenna pattern formed on one surface of the dielectric layer and a parasitic antenna pattern formed on the other surface of the dielectric layer opposite to the one surface; a first rewiring structure electrically connected to the active antenna pattern of the antenna structure; a molding body formed on one surface of the first rewiring structure; a semiconductor chip placed within the molding body; a second rewiring structure formed on one surface of the molding body; a vertical connection conductor laterally spaced from the semiconductor chip, penetrating the molding layer, and electrically connecting the second rewiring structure and the first rewiring structure; and an external connection terminal formed on one surface of the second rewiring structure.

### CROSS-REFERENCE TO RELATED APPLICATION

This application claims priority to and the benefit of Korean Patent Application No. 10-2022-0180979, filed on Dec. 21, 2022, the disclosure of which is incorporated herein by reference in its entirety.

### BACKGROUND

### Technical Field

The present invention relates to a semiconductor package and a method of manufacturing a semiconductor package, and more specifically to a semiconductor package including an antenna for transmitting and receiving wireless signals.

### Background Art

The use of semiconductor chips in electronic devices is increasing. Semiconductor chips are widely applied due to the advantages of small size, light weight, high reliability and the ease of mass production.

Meanwhile, in order to easily handle these semiconductor chips, semiconductor packages integrate all components that are required for a specific function into one chip and packages the components into one unit product.

These semiconductor packages may include devices, such as semiconductors, resistors and capacitors, and conductive wires connecting the devices.

Additionally, if the semiconductor chip needs to transmit or receive wireless signals, an antenna may be included in the semiconductor package.

In order to integrate the antenna into the semiconductor package, a redistribution layer is formed on one surface and the other surface of the semiconductor package, respectively, and after an external connection terminal is formed on one of the same, an antenna structure can be attached to the remaining one on which the external connection terminal is not formed to integrate the same.

Additionally, the antenna structure is configured by forming antenna patterns on both surfaces of a dielectric layer that is made of a material such as epoxy or FR-4.

However, the semiconductor package and antenna structure are manufactured separately, and it is manufactured in the form of attaching the separately manufactured semiconductor package and antenna structure.

In addition, when manufacturing the semiconductor package, it is built up on a carrier, and in order to mount the antenna structure, a redistribution layer must be formed on both surfaces of the semiconductor chip, and thus, since the number of times the carrier is attached and detached during the manufacturing process is high, there have been problems in that the manufacturing process is complicated and the manufacturing costs are increased.

In addition, the antenna structure is formed by aligning antenna patterns on both surfaces of the dielectric layer as described above, and since the dielectric layer is made of an opaque material, it is difficult to form the antenna patterns formed on both surfaces of the dielectric layer in an accurately aligned state, and in order to achieve this, there have been problems in that the manufacturing process is complicated and the manufacturing costs are increased.

### SUMMARY

The present invention is intended to solve the above problems, and an object of the present invention is to provide a semiconductor package that can be manufactured in a more simplified process and a manufacturing method of a semiconductor package.

The problems of the present invention are not limited to the problems mentioned above, and other problems that are not mentioned will be clearly understood by those skilled in the art from the description below.

According to an aspect of the present invention, provided is a semiconductor package, including an antenna structure which includes a dielectric layer that is made of a transparent material, an active antenna pattern that is formed on one surface of the dielectric layer and a parasitic antenna pattern that is formed on the other surface of the dielectric layer opposite to the one surface; a first rewiring structure which is electrically connected to the active antenna pattern of the antenna structure; a molding body which is formed on one surface of the first rewiring structure; a semiconductor chip which is placed within the molding body; a second rewiring structure which is formed on one surface of the molding body; a vertical connection conductor which is laterally spaced from the semiconductor chip, penetrates the molding layer, and electrically connects the second rewiring structure and the first rewiring structure; and an external connection terminal which is formed on one surface of the second rewiring structure.

The dielectric layer of the antenna structure may be made of a glass material.

The dielectric layer of the antenna structure may be a carrier on which the first rewiring structure, the molding body and the second rewiring structure are formed.

The thickness of the dielectric layer may be between 100 micrometers and 500 micrometers.

The semiconductor package may further include a protective layer for covering and protecting the other surface of the dielectric layer and the parasitic antenna pattern.

According to another aspect of the present invention, provided is a method for manufacturing a semiconductor package, including an active antenna pattern formation step of forming an active antenna pattern on one surface of a carrier that is made of a transparent glass material; a first rewiring step of forming a first rewiring structure on the surface of the carrier on which the antenna pattern is formed; a chip placement step of placing a semiconductor chip on the first rewiring structure; a molding step of forming a molding body by molding a molding agent on the first rewiring structure on which the semiconductor chip is disposed; a second rewiring step of forming a second rewiring structure on one surface of the molding body; and an individualization step of individualizing the first rewiring structure, molding body, semiconductor chip and second rewiring structure by cutting the same together with the carrier that is made of the glass material.

After the active antenna pattern formation step, a parasitic antenna pattern formation step may be performed by inverting the carrier to form a parasitic antenna pattern on the other surface opposite to the one surface of the carrier.

Before the active antenna pattern formation step, a parasitic antenna pattern formation step may be performed by inverting the carrier to form a parasitic antenna pattern on the other surface opposite to the one surface of the carrier.

Meanwhile, according to still another aspect of the present invention, disclosed is a method for manufacturing a semiconductor package, including an active antenna pattern formation step of forming an active antenna pattern on one surface of a carrier that is made of a transparent glass material; a first rewiring step of forming a first rewiring structure on the surface of the carrier on which the antenna pattern is formed; a chip placement step of placing a semiconductor chip on the first rewiring structure; a molding step of forming a molding body by molding a molding agent on the first rewiring structure on which the semiconductor chip is disposed; a second rewiring step of forming a second rewiring structure on one surface of the molding body; an inversion step of inverting the carrier and the first rewiring structure, molding body, semiconductor chip and second rewiring structure that are built up on the carrier; a parasitic antenna pattern formation step of forming a parasitic antenna pattern on the other surface of the inverted carrier by aligning the same with the active antenna pattern; and an individualization step of individualizing the first rewiring structure, molding body, semiconductor chip and second rewiring structure by cutting the same together with the carrier that is made of the glass material.

According to the above configuration, since the semiconductor package and manufacturing method of a semiconductor package according to the present invention can be built up by using a carrier for manufacturing a semiconductor package as the dielectric layer of an antenna structure, there is no process of attaching or detaching the carrier during the semiconductor package manufacturing process, and alternatively, it can be minimized, which has the effect of simplifying the manufacturing process.

In addition, since the carrier made of a glass material having a transparent material is used as the dielectric layer, it is very easy to align the antenna patterns that are formed on one surface and the other surface of the dielectric layer, thereby further simplifying the manufacturing process.

In addition, by using a glass material with excellent dielectric constant, the characteristics of the antenna structure can be improved, and as the thickness of a dielectric layer made of a glass material is formed to be thicker, the characteristics of the antenna structure are improved, and moreover, it is possible to prevent the distortion of a semiconductor package.

The effects of the present invention are not limited to the effects described above, but should be understood to include all effects that can be inferred from the configuration of the invention described in the Detailed Description or claims of the present invention.

### BRIEF DESCRIPTION OF THE DRAWINGS

FIG. 1 is a diagram illustrating a semiconductor package according to an exemplary embodiment of the present invention.

FIGS. 2 to 5 are diagrams illustrating the step-by-step manufacturing of a semiconductor package according to an exemplary embodiment of the present invention.

FIG. 2 (a) is a diagram illustrating a state in which a carrier is prepared; (b) is a diagram illustrating a state in which an active antenna pattern is formed on the carrier.

FIG. 3 (a) is a diagram illustrating a state in which a first rewiring structure is formed on one surface where the active antenna pattern of the carrier is formed; (b) is a diagram illustrating a state in which a semiconductor chip is mounted on the first rewiring structure.

FIG. 4 (a) is a diagram illustrating a molding body formed on the first rewiring structure on which the semiconductor chip is mounted; (b) is a diagram illustrating a second rewiring structure formed on the molding body.

FIG. 5 (a) is a diagram illustrating a state in which a parasitic antenna pattern is formed on the other surface of the carrier after the semiconductor package on which the second rewiring structure is formed is inverted along with the carrier; (b) is a diagram illustrating an individualized semiconductor package.

FIG. 6 is a flowchart illustrating the manufacturing method of a semiconductor package according to an exemplary embodiment of the present invention.

FIG. 7 is a flowchart illustrating the manufacturing method of a semiconductor package according to another exemplary embodiment of the present invention.

### DETAILED DESCRIPTION OF THE INVENTION

Hereinafter, with reference to the attached drawings, the exemplary embodiments of the present invention will be described in detail so that those skilled in the art can easily practice the present invention. The present invention may be implemented in many different forms and is not limited to the exemplary embodiments described herein. In order to clearly describe the present invention, parts that are irrelevant to the description have been omitted in the drawings, and the same or similar components are assigned the same reference numerals throughout the specification.

Terms and words used in the present specification and claims should not be construed as limited to their usual or dictionary definition, and they should be interpreted as a meaning and concept consistent with the technical idea of the present invention based on the principle that inventors may appropriately define the terms and concept in order to describe their own invention in the best way.

Accordingly, the exemplary embodiments described in the present specification and the configurations shown in the drawings correspond to preferred exemplary embodiments of the present invention, and do not represent all the technical spirit of the present invention, and thus, the configurations may have various examples of equivalent and modification that can replace them at the time of filing the present invention.

It is understood that the terms “include” or “have”, when used in the present specification, are intended to describe the presence of stated features, integers, steps, operations, elements, components and/or a combination thereof, but not preclude the possibility of the presence or addition of one or more other features, integers, steps, operations, elements, components or a combination thereof.

The presence of an element in/on “front”, “rear”, “upper or above or top” or “lower or below or bottom” of another element includes not only being disposed in/on “front”, “rear”, “upper or above or top” or “lower or below or bottom” directly in contact with other elements, but also cases in which another element being disposed in the middle, unless otherwise specified. In addition, unless otherwise specified, that an element is “connected” to another element includes not only direct connection to each other but also indirect connection to each other.

Hereinafter, the semiconductor package according to an exemplary embodiment of the present invention will be described with reference to the drawings.

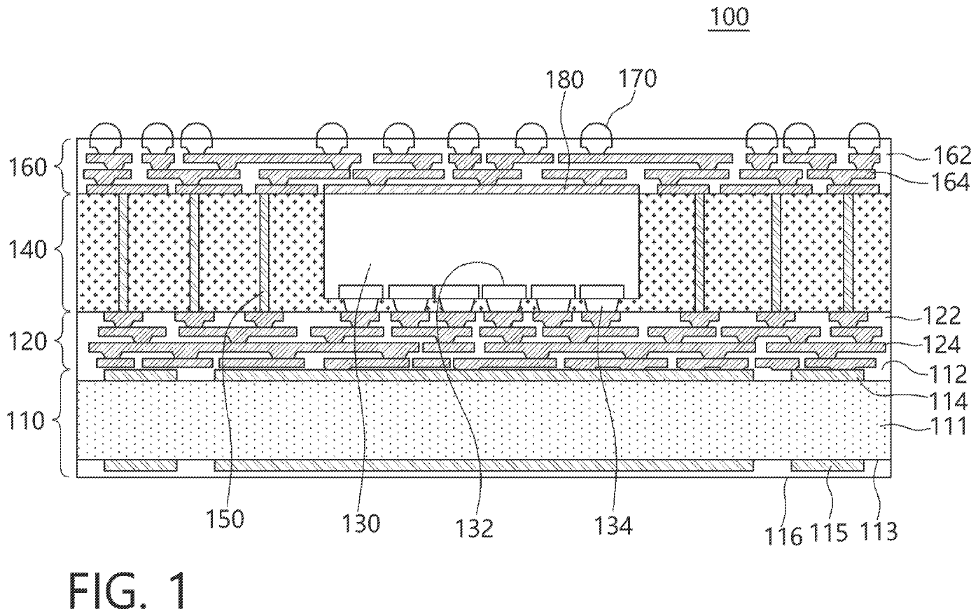

FIG. 1 is a diagram illustrating a semiconductor package according to an exemplary embodiment of the present invention.

As illustrated in FIG. 1, the semiconductor package 100 according to the present embodiment may include an antenna structure 110, a first rewiring structure 120, a molding body 140, a semiconductor chip 130, a second rewiring structure 160, a vertical connection conductor 150 and an external connection terminal 170.

The antenna structure 110 is a component that receives or transmits wireless signals from the outside, and it may include a dielectric layer 111, an active antenna pattern 114 and a parasitic antenna pattern 115.

The dielectric layer 111 may be formed in the form of a flat plate, and one surface 112 and the other surface 113, which are flat surfaces, may be formed on opposite surfaces.

Hereinafter, the horizontal direction is defined as a direction parallel to one surface 112 of the dielectric layer 111 (e.g., X direction and/or Y direction), and the vertical direction is defined as a direction perpendicular to one surface 112 of the dielectric layer 111 (e.g., Z direction). In addition, the horizontal width or horizontal distance may be a length along the horizontal direction (e.g., X direction and/or Y direction), and the thickness, vertical width or vertical distance may be a length along the vertical direction (e.g., Z direction).

The dielectric layer 111 may be made of a transparent material. For example, it may be glass. Certainly, the dielectric layer 111 of the present invention is not necessarily limited to a glass material, and various transparent materials, such as sapphire, quartz, ceramic, SiC and Al₂O₃ with transparent characteristics, may be applied.

However, in the description of the present embodiment, it will be described by taking as an example that the dielectric layer 111 is made of a transparent glass material, and it is the same material as a carrier 111 that is used when manufacturing the semiconductor package 100.

Additionally, the dielectric layer 111 may be configured to have low dielectric constant and low dielectric loss characteristics. For example, the dielectric constant of the dielectric layer 111 may be 6 or less, or 5 or less. For example, the dielectric loss (dissipation factor) of the dielectric layer 111 may be 0.009 or less, 0.007 or less, 0.005 or less, or 0.003 or less.

Additionally, the dielectric layer 111 may have a transmittance of 30 to 100%.

The thickness of the dielectric layer 111 may be between 50 micrometers and 350 micrometers, or between 100 micrometers and 500 micrometers. Certainly, these are numerical values that may vary depending on the specifications of the product to be manufactured.

The active antenna pattern 114 may be formed on one surface 112 of the dielectric layer 111 facing the semiconductor chip 130. The active antenna pattern 114 may have a structure and shape that are suitable for performing communication in a predetermined wavelength band. For example, the active antenna pattern 114 may be configured to radiate or receive a radio signal in the millimeter wavelength band, and it may include a patch antenna or dipole antenna so as to function as a radiator of the antenna or a director of the antenna.

Additionally, the spacing between two neighboring active antenna patterns 114 may be between 10% and 400%, between 30% and 300%, or between 50% and 150% of the horizontal width of the active antenna patterns 114. Alternatively, the spacing between two neighboring active antenna patterns 114 may be equal to the horizontal width of the active antenna patterns 114.

Meanwhile, the active antenna pattern 114 may include at least one first active antenna pattern 114 which is configured to radiate or receive a wireless signal in a first wavelength band, and at least one second active antenna pattern 114 which is configured to radiate or receive a wireless signal in a second wavelength band that is different from the first wavelength band. The first active antenna pattern 114 and the at least one second active antenna pattern 114 may be electrically connected to the semiconductor chip 130 through different electrical connection paths.

The first active antenna pattern 114 and the second active antenna pattern 114 may have different shapes and/or different dimensions (e.g., different horizontal widths).

The parasitic antenna pattern 115 may be formed to be disposed on the surface of the other surface 113 of the dielectric layer 111. The parasitic antenna pattern 115 may function to expand the bandwidth of wireless communication using the active antenna pattern 114.

The parasitic antenna pattern 115 may be spaced apart from the active antenna pattern 114 in a vertical direction (e.g., Z direction) with the dielectric layer 111 interposed therebetween. The parasitic antenna pattern 115 may be a patch antenna having a polygonal shape, such as a circle or square, or may be a line shape that is formed on the other surface 113 of the dielectric layer 111.

Additionally, the antenna structure 110 may further include a protective layer 116 for covering the other surface 113 of the dielectric layer 111 and the parasitic antenna pattern 115.

The parasitic antenna pattern 115 may have the same shape as the active antenna pattern 114 from a plan view, and the parasitic antenna pattern 115 and the active antenna pattern 114 may overlap from a plan view.

Certainly, the present invention is not limited thereto, and the shape of the parasitic antenna pattern 115 may be different from the shape of the active antenna pattern 114.

Additionally, as the protective layer 116 is omitted, the parasitic antenna pattern 115 may be exposed to the outside.

Additionally, the parasitic antenna pattern 115 may include a dielectric layer 111, and the active antenna pattern 114 and the parasitic antenna pattern 115 may include a conductive material. For example, the active antenna pattern 114 and the parasitic antenna pattern 115 may include a metal such as copper (Cu) or aluminum (Al).

As described above, the parasitic antenna pattern 115 may be formed to overlap the active antenna pattern 114 in a planar manner, and in this case, the parasitic antenna pattern 115 must be formed in an aligned state with the active antenna pattern 114. It.

However, since the dielectric layer 111 is formed of a transparent material, when the parasitic antenna pattern 115 is formed on the other surface 113 of the dielectric layer 111, the formation position of the active antenna pattern 114 may be seen through the other surface of the dielectric layer 111, and thus, it is possible to easily identify the alignment position with the active antenna pattern 114.

The first rewiring structure 120 is provided on one surface 112 of the dielectric layer 111, and it may function as a mounting substrate on which the semiconductor chip 130 is mounted. The first rewiring structure may include a plurality of first rewiring insulating layers 122 and a first rewiring pattern 124.

The plurality of first rewiring insulating layers 122 may be stacked on one surface 112 of the dielectric layer 111 in a vertical direction. The plurality of first rewiring insulating layers 122 may be formed of insulating polymer, epoxy or a combination thereof. Each of the plurality of first rewiring insulating layers 122 may be formed of a material that is different from the material constituting the dielectric layer 111. For example, the dielectric constant of each of the plurality of first rewiring insulating layers 122 may be different from the dielectric constant of the dielectric layer 111.

Additionally, the first rewiring pattern 124 is formed in each of the plurality of first rewiring insulating layers 122, and it may extend horizontally or vertically to form electrical wiring.

The first rewiring pattern 124 is electrically connected to the semiconductor chip 130, which will be described below, and it may also be connected to the active antenna pattern 114 of the antenna structure 110.

The semiconductor chip 130 may be mounted on the first rewiring structure 120 using a flip chip method. The semiconductor chip 130 may include an upper and lower surface that are opposite to each other, and the lower surface of the semiconductor chip 130 may be a pad surface on which the chip pad 132 is provided. The semiconductor chip 130 may be mounted on the first rewiring structure 120 such that the lower surface where the chip pad 132 is provided faces the first rewiring structure 120. A chip connection bump 134, such as a micro bump 134, may be disposed between the semiconductor chip 130 and the first rewiring structure 120. The semiconductor chip 130 may be electrically connected to the first rewiring pattern 124 of the first rewiring structure 120 through the chip connection bump 134.

A plurality of various types of individual devices may be formed on the semiconductor chip 130. For example, the plurality of individual devices may be various microelectronic devices, such as metal-oxide semiconductor field effect transistors (MOSFET) such as complementary metal-oxide-semiconductor transistors (CMOS transistor), the system large scale integration (LSI), image sensors such as CMOS imaging sensors (CIS), the micro-electromechanical system (MEMS), Power Management (PM) IC, active devices, passive devices and the like.

The semiconductor chip 130 is a communication semiconductor chip 130 which is connected electrically or capable of transmitting signals to the antenna structure 110, and it may include a signal processing circuit for processing wireless signals that are transmitted and received through the antenna structure 110. For example, the semiconductor chip 130 may include a radio-frequency integrated circuit (RFIC).

The semiconductor chip 130 may be a memory chip. The memory chip may be a volatile memory chip, such as DRAM (Dynamic Random Access Memory) or SRAM (Static Random Access Memory), or a non-volatile memory chip, such as PRAM (Phase-change Random Access Memory), MRAM (Magnetoresistive Random Access Memory), FeRAM (Ferroelectric Random Access Memory) or RRAM (Resistive Random Access Memory).

Alternatively, the semiconductor chip 130 may be a logic chip. The semiconductor chip 130 may be a Central Processor Unit (CPU), Micro Processor Unit (MPU), Graphic Processor Unit (GPU) or Application Processor (AP).

The semiconductor package 100 may include one semiconductor chip 130 or two or more semiconductor chips 130. Two or more semiconductor chips 130 included in the semiconductor package 100 may be the same type of semiconductor chips 130 or may be different types of semiconductor chips 130.

The semiconductor package 100 may be a system in package in which the different types of semiconductor chips 130 and various electronic components are electrically connected to each other and operate as a single system.

In addition, although not illustrated, one or more passive components, such as a capacitor, inductor, resistor and integrated passive device (IPD), may be mounted on the first rewiring structure 120. Certainly, whether the passive components are mounted may vary depending on the type of semiconductor package 100 being manufactured.

The molding body 140 is provided on the first rewiring structure 120, and it may cover at least a portion of the semiconductor chip 130. In the present exemplary embodiment, the molding body 140 may cover the side surfaces of the semiconductor chip 130, but may not cover the upper surface of the semiconductor chip 130. In this case, the upper surface of the molding body 140 may be on the same plane as the upper surface of the semiconductor chip 130.

Alternatively, the molding body 140 may cover the top and side surfaces of the semiconductor chip 130. In addition, the molding body 140 may be filled in the gap between the semiconductor chip 130 and the first rewiring structure 120, and surround the chip connection bump 134 between the semiconductor chip 130 and the first rewiring structure. The molding body 140 may be formed of, for example, an epoxy molding compound, but the present invention is not limited thereto.

The vertical connection conductor 150 is provided within the molding body 140, and it may be spaced laterally from the semiconductor chip 130. The vertical connection conductor 150 extends in a generally vertical direction within the molding body 140, and it may penetrate the molding body 140.

The lower surface of the vertical connection conductor 150 may contact the first rewiring structure 120, and the upper surface of the vertical connection conductor 150 may contact the second rewiring structure 160.

The vertical connection conductor 150 may be made of copper (Cu), aluminum (Al), solder, tin (Sn), zinc (Zn), lead (Pb), silver (Ag), gold (Au), palladium (Pd) or a combination of these materials.

The vertical connection conductor 150 may include a conductive wire that is formed through a bonding wire process.

The second rewiring structure 160 may be formed on the molding body 140 and the semiconductor chip 130. The second rewiring structure 160 may include a plurality of second rewiring insulating layers 162 and a second rewiring pattern 164.

A plurality of second rewiring insulating layers 162 are formed on the upper surface of the molding body 140, and they may be stacked on each other in a vertical direction. The plurality of second rewiring insulating layers 162 may be formed of insulating polymer, epoxy or a combination thereof.

The plurality of second rewiring insulating layers 162 may be formed of a material that is different from the material constituting the dielectric layer 111.

That is, the dielectric constant of each of the plurality of second rewiring line insulating layers may be different from the dielectric constant of the dielectric layer 111.

The second rewiring pattern 164 is formed on each of the plurality of second rewiring insulating layers 162, and it may extend horizontally or vertically to form electrical wiring.

The external connection terminal 170 is attached to the second rewiring structure 160, and it may electrically connect between the semiconductor package 100 and an external device.

The heat dissipation pad is in contact with the upper surface of the semiconductor chip 130, and it may cover at least a portion of the upper surface of the semiconductor chip 130. The heat dissipation pad may completely or partially cover the upper surface of the semiconductor chip 130.

The heat dissipation pad covers the upper surface of the semiconductor chip 130, and furthermore, it may also protrude laterally from the side of the semiconductor chip 130 to further cover the upper surface of the molding body 140. The planar area of the heat dissipation pad may be larger than the planar area of the semiconductor chip 130, and it may be formed to cover the entire upper surface of the semiconductor chip 130 and a portion of the upper surface of the molding body 140 around the semiconductor chip 130.

A heat dissipation pad 180 may not be electrically connected to the semiconductor chip 130. Additionally, the heat dissipation pad 180 may be electrically grounded and shield electromagnetic interference with the semiconductor chip 130.

Meanwhile, the semiconductor chip 130 is disposed with the surface on which the chip pad 132 is formed facing the antenna structure 110, and the semiconductor chip 130 may be electrically connected to the active antenna pattern 114 of the antenna structure 110 through the first rewiring pattern 124 of the first rewiring structure 120. Accordingly, the length of the signal transmission path between the semiconductor chip 130 and the antenna structure 110 is reduced, thereby reducing signal loss and improving antenna radiation characteristics.

In addition, since the carrier 111 made of a glass material having a transparent material is used as the dielectric layer 111, it may be very easy to align the antenna patterns that are formed on one surface and the other surface of the dielectric layer 111.

In addition, since a glass material with excellent dielectric constant is used as the dielectric layer 111, the characteristics of the antenna structure 110 may become more excellent, and as the thickness of the dielectric layer 111 made of a glass material is formed to be thicker, the characteristics of the antenna structure 110 are improved, and moreover, it is possible to prevent the distortion of the semiconductor package 100.

Hereinafter, an exemplary embodiment of the manufacturing method of a semiconductor package 100 for manufacturing the semiconductor package 100 of the present invention will be described.

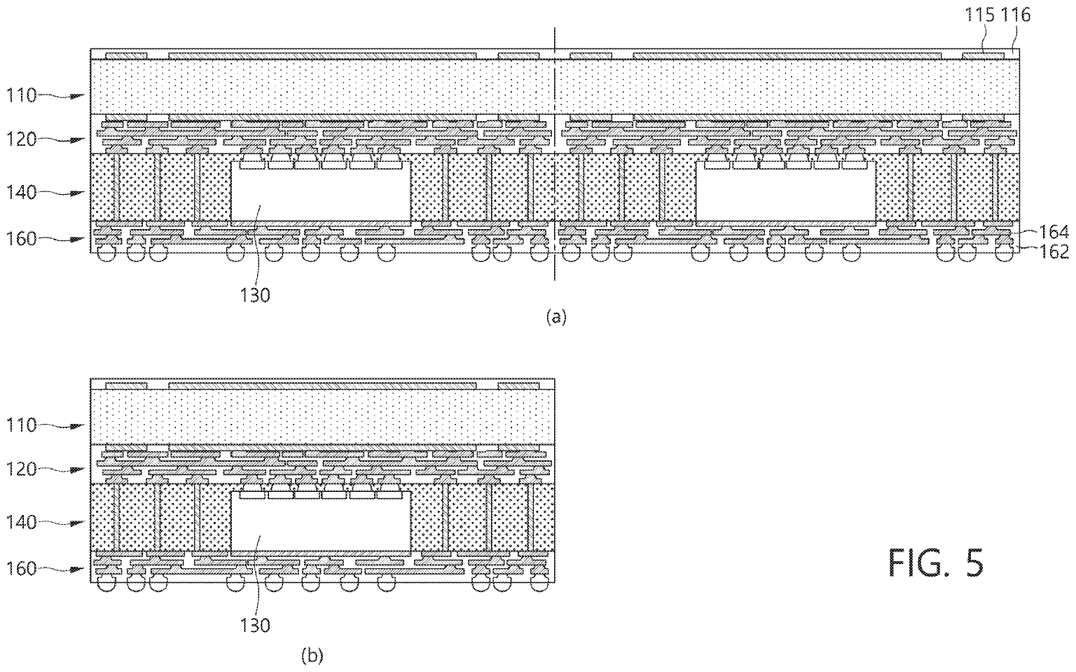

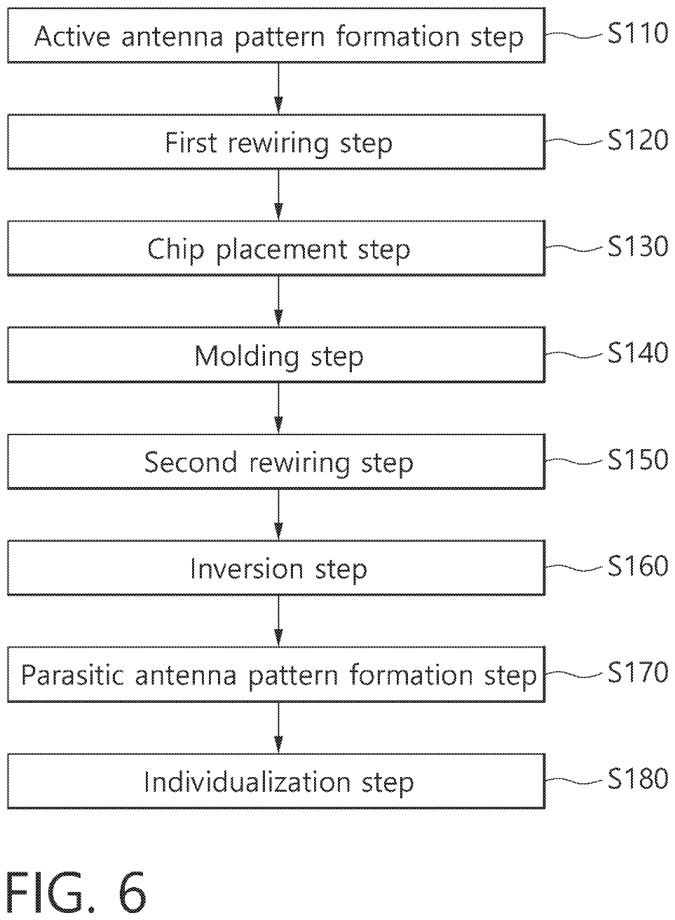

As illustrated in FIG. 5, the method for manufacturing a semiconductor package 100 according to the present exemplary embodiment may include an active antenna pattern formation step (S110), a first rewiring step (S120), a chip placement step (S130), a molding step (S140), a second rewiring step (S150), an inversion step (S160), a parasitic antenna formation step (S170) and an individualization step (S180).

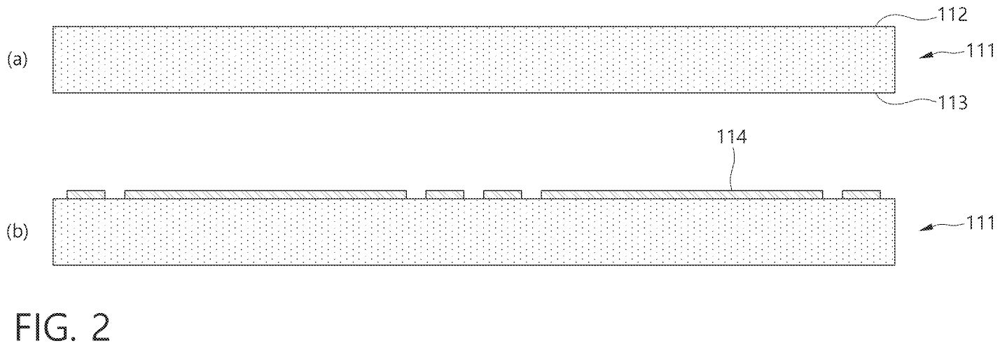

First of all, as illustrated in (a) of FIG. 2, a carrier 111 may be prepared. The carrier 111 may be made of a transparent glass material.

The active antenna pattern 114 formation step is a step of forming an active antenna pattern 114 on one surface 112 of the prepared carrier 111 which is made of a transparent glass material, as illustrated in (b) of FIG. 2.

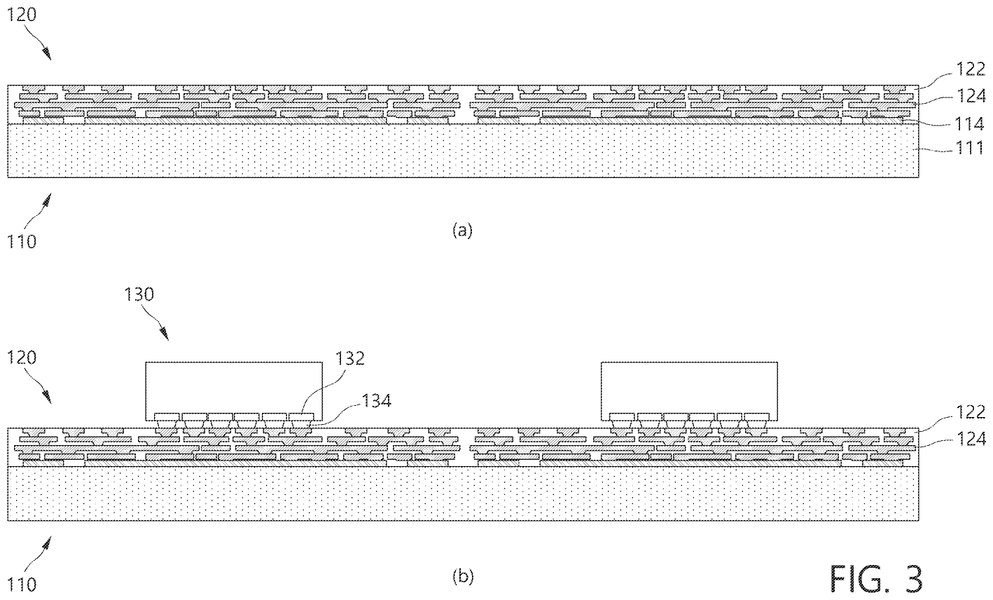

After the active antenna pattern 114 is formed on the carrier 111, the first rewiring step (S120) of building up a first rewiring structure 120 may be performed as illustrated in FIG. 3 (a).

In the first rewiring step (S120), a first rewiring insulating layer 122 and a first rewiring pattern 124 may be built up on one surface 112 of the carrier 111 on which the active antenna pattern 114 is formed to form a first rewiring structure 120.

In addition, as illustrated in b of FIG. 3, the chip placement step (S130) may be performed. The chip placement step (S130) is a step of placing a semiconductor chip 130 on the first rewiring structure 120.

If the semiconductor package 100 to be manufactured includes passive components in addition to the semiconductor chip 130, they may be placed together with the semiconductor chip 130 in the chip placement step (S130).

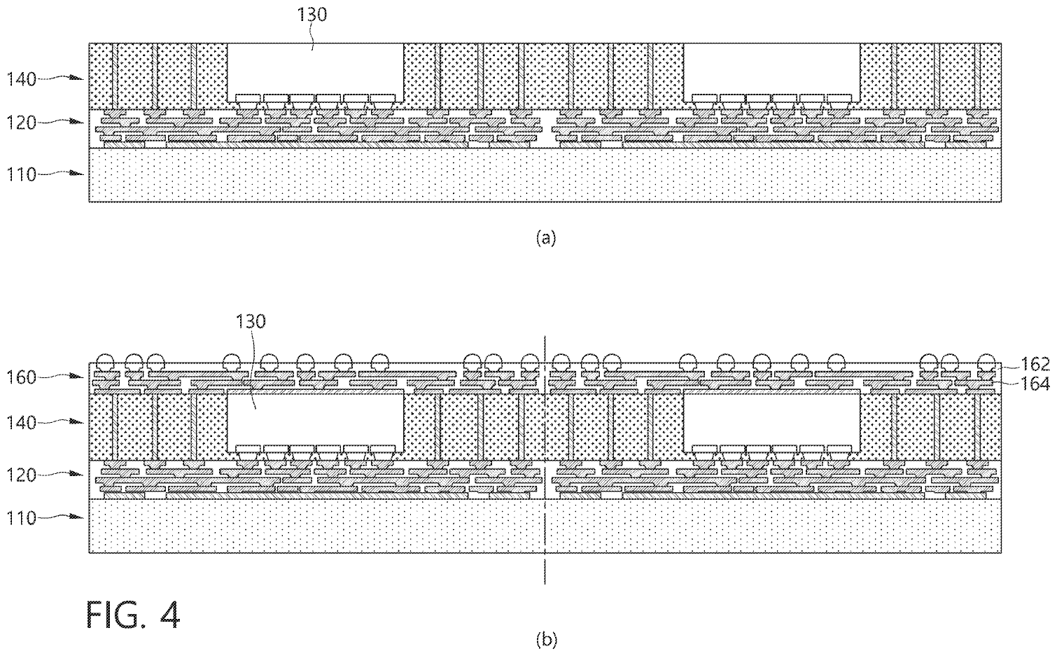

Next, the molding step (S140) may be performed. As illustrated in (a) in FIG. 4, the molding step (S140) is a step of forming a molding body 140 by molding a molding agent on the first rewiring structure 120 on which the semiconductor chip 130 is placed.

After forming the molding body 140 in the molding step (S140), a vertical connection conductor 150 may be formed through drilling or the like.

Alternatively, the vertical connection conductor 150 may be formed in advance before forming the molding body 140.

In addition, after the molding step (S140), a grinding step of exposing the upper surface of the semiconductor chip 130 by grinding a portion of the molding body 140 may be performed.

In addition, after the molding step (S140), a second rewiring step (S150) may be performed. In the second rewiring step (S150), as illustrated in (b) of FIG. 4, a second rewiring insulating layer 162 and a second rewiring pattern 164 may be formed on one surface 112, which is the upper surface of the molding body 140 formed in the molding step (S140).

Additionally, after the second rewiring step (S150) is completed, an external connection terminal 170 may be formed.

After the second rewiring step (S150) is completed, as illustrated in (a) in FIG. 5, the inversion step (S160) is performed to turn over the built-up semiconductor package, and after the inversion, the parasitic antenna pattern formation step (S170) of forming a parasitic antenna pattern 115 on the other surface 113 of the carrier 111 is performed.

Through the active antenna pattern formation step (S110) and the parasitic antenna pattern formation step (S170), an active antenna pattern 114 and a parasitic antenna pattern 115 may be formed on one surface 112 and the other surface 113 of the carrier 111.

Since the active antenna pattern 114 and the parasitic antenna pattern 115 are formed on one surface 112 and the other surface 113 of the carrier 111, the carrier 111 may serve as a dielectric layer 111 of the antenna structure 110.

In addition, since the carrier 111 is a transparent material, it may be easy to align the active antenna pattern 114 and the parasitic antenna pattern 115 when forming the parasitic antenna pattern 115 or the active antenna pattern 114.

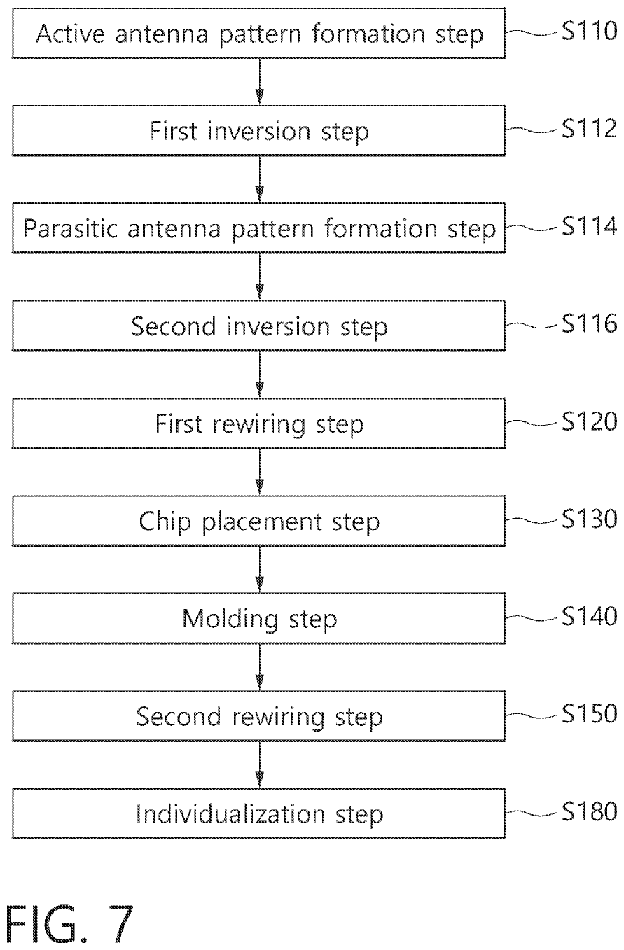

Certainly, in addition to the above-described manufacturing method, as illustrated in FIG. 7, it may be manufactured in the order of an active antenna pattern formation step (S110), a first inversion step (S112), a parasitic antenna pattern formation step (S114), a second inversion step (S116), a first rewiring step (S120), a chip placement step (S130), a molding step (S140), a second rewiring step (S150) and an individualization step (S180).

That is, after forming an active antenna pattern 114 on one surface of the carrier 111, the carrier 111 is inverted through the first inversion step (S112), and after performing the parasitic antenna pattern formation step (S114) of forming a parasitic antenna pattern 115 on the other surface 113 of the inverted carrier 111, the second inversion step (S116) of inverting the carrier 111 again may be performed.

When forming the parasitic antenna pattern 115, it must be aligned with the active antenna pattern 114, and since the carrier 111 is transparent, the formation position of the active antenna pattern 114 on the other surface of the carrier 111 is confirmed, and thus, the formation position of the parasitic antenna pattern 115 may be easily aligned.

Next, the first rewiring step (S120), the chip placement step (S130), the molding step (S140), the second rewiring step (S150) and the individualization step (S180) may be performed sequentially on one surface of the carrier on which the active antenna pattern 114 and parasitic antenna pattern 115 are formed.

Alternatively, the parasitic antenna pattern 115 is formed on the other surface of the carrier 111 before forming the active antenna pattern 114, and then, after the carrier 111 is inverted, an active antenna pattern 114 may be formed on one surface of the carrier 111, and the first rewiring structure 120 may be built up.

The individualization step (S180) of individualizing the separate semiconductor package 100 as illustrated in FIG. 5 (b) may be performed by cutting the first rewiring structure 120, molding body 140, semiconductor chip 130 and second rewiring structure 160 formed in the above-described steps together with the carrier 111 that is made of a glass material.

That is, the carrier 111 not only serves as a substrate for building up the semiconductor package 100, but also serves as the dielectric layer 111 of the antenna structure 110.

Therefore, since the carrier 111 made of a transparent glass material serves as the dielectric layer 111 of the antenna structure 110, the alignment position may be more easily identified when forming the active antenna pattern 114 and the parasitic antenna pattern 115.

In addition, since a glass material with excellent dielectric constant is used, the characteristics of the antenna structure 110 may become more excellent, and as the thickness of the dielectric layer 111 made of a glass material is formed to be thicker, the characteristics of the antenna structure 110 are improved, and also, it is possible to prevent the distortion of the semiconductor package 100.

In addition, since it is possible to build up by using the carrier 111 for manufacturing the semiconductor package 100 as the dielectric layer 111 of the antenna structure 110, the process of attaching and detaching the carrier 111 during the manufacturing process of the semiconductor package 100 may be eliminated or minimized, which has the effect of simplifying the manufacturing process.

Although the exemplary embodiments of the present invention have been described, the spirit of the present invention is not limited to the exemplary embodiments presented in the present specification, and those skilled in the art who understand the spirit of the present invention may easily suggest other exemplary embodiments by changing, modifying, deleting or adding components within the scope of the same spirit, but this will also fall within the scope of the present invention.

### EXPLANATION OF REFERENCE NUMERALS

| | |
|---|---|
| 100: Semiconductor package | 110: Antenna structure |
| 111: Dielectric layer | 111: Carrier |
| 112: One surface | 113: Other surface |
| 114: Active antenna pattern | 115: Parasitic antenna pattern |
| 116: Protective layer | 120: First rewiring structure |
| 122: First rewiring insulating layer | 124: First rewiring pattern |
| 130: Semiconductor chip | 132: Chip pad |
| 134: Bump | 140: Molding body |
| 150: Vertical connection conductor | 160: Second rewiring structure |

162: Second rewiring insulating layer
164: Second rewiring pattern

| | |
|---|---|
| 170: External connection terminal | 180: Heat dissipation pad |

S110: Active antenna pattern formation step
S120: First inversion step
S130: Parasitic antenna pattern formation step

| | |
|---|---|
| S140: Second inversion step | S150: First rewiring step |
| S160: Chip placement step | S170: Molding step |
| S180: Second rewiring step | S190: Individualization step |

1. A semiconductor package, comprising:
an antenna structure which comprises a dielectric layer that is made of a transparent material, an active antenna pattern that is formed on one surface of the dielectric layer and a parasitic antenna pattern that is formed on the other surface of the dielectric layer opposite to the one surface;
a first rewiring structure which is electrically connected to the active antenna pattern of the antenna structure;
a molding body which is formed on one surface of the first rewiring structure;
a semiconductor chip which is placed within the molding body;
a second rewiring structure which is formed on one surface of the molding body;
a vertical connection conductor which is laterally spaced from the semiconductor chip, penetrates the molding layer, and electrically connects the second rewiring structure and the first rewiring structure; and
an external connection terminal which is formed on one surface of the second rewiring structure.

2. The semiconductor package of claim 1, wherein the dielectric layer of the antenna structure is made of a glass material.

3. The semiconductor package of claim 1, wherein the dielectric layer of the antenna structure is a carrier on which the first rewiring structure, the molding body and the second rewiring structure are formed.

4. The semiconductor package of claim 1, wherein the thickness of the dielectric layer is between 100 micrometers and 500 micrometers.

5. The semiconductor package of claim 1, further comprising:
a protective layer for covering and protecting the other surface of the dielectric layer and the parasitic antenna pattern.

6. A method for manufacturing a semiconductor package, comprising:
an active antenna pattern formation step of forming an active antenna pattern on one surface of a carrier that is made of a transparent glass material;
a first rewiring step of forming a first rewiring structure on the surface of the carrier on which the antenna pattern is formed;
a chip placement step of placing a semiconductor chip on the first rewiring structure;
a molding step of forming a molding body by molding a molding agent on the first rewiring structure on which the semiconductor chip is disposed;
a second rewiring step of forming a second rewiring structure on one surface of the molding body; and
an individualization step of individualizing the first rewiring structure, molding body, semiconductor chip and second rewiring structure by cutting the same together with the carrier that is made of the glass material.

7. The method of claim 6, wherein after the active antenna pattern formation step, a parasitic antenna pattern formation step is performed by inverting the carrier to form a parasitic antenna pattern on the other surface opposite to the one surface of the carrier.

8. The method of claim 6, wherein before the active antenna pattern formation step, a parasitic antenna pattern formation step is performed by inverting the carrier to form a parasitic antenna pattern on the other surface opposite to the one surface of the carrier.

9. A method for manufacturing a semiconductor package, comprising:
an active antenna pattern formation step of forming an active antenna pattern on one surface of a carrier that is made of a transparent glass material;
a first rewiring step of forming a first rewiring structure on the surface of the carrier on which the antenna pattern is formed;
a chip placement step of placing a semiconductor chip on the first rewiring structure;
a molding step of forming a molding body by molding a molding agent on the first rewiring structure on which the semiconductor chip is disposed;
a second rewiring step of forming a second rewiring structure on one surface of the molding body;
an inversion step of inverting the carrier and the first rewiring structure, molding body, semiconductor chip and second rewiring structure that are built up on the carrier;
a parasitic antenna pattern formation step of forming a parasitic antenna pattern on the other surface of the inverted carrier by aligning the same with the active antenna pattern; and
an individualization step of individualizing the first rewiring structure, molding body, semiconductor chip and second rewiring structure by cutting the same together with the carrier that is made of the glass material.
